(19) United States
(12) Patent Application Publication
(10) Pub. No.: US 2023/0301091 A1
(43) Pub. Date: Sep. 21, 2023

(54) SEMICONDUCTOR DEVICE AND MANUFACTURING METHOD OF THE SEMICONDUCTOR DEVICE

(71) Applicant: SK hynix Inc., Icheon-si Gyeonggi-do (KR)

(72) Inventors: Sung Wook JUNG, Icheon-si Gyeonggi-do (KR); Ji Hui BAEK, Icheon-si Gyeonggi-do (KR); Jang Hee JUNG, Icheon-si Gyeonggi-do (KR)

(73) Assignee: SK hynix Inc., Icheon-si Gyeonggi-do (KR)

(21) Appl. No.: 17/891,655

(22) Filed: Aug. 19, 2022

(30) Foreign Application Priority Data
Mar. 17, 2022 (KR) 10-2022-0033604

(51) Int. Cl. H01L 27/11582; H01L 23/528; H01L 27/11556; H01L 27/11519; H01L 27/11565

(52) U.S. Cl. CPC H01L 27/11582; H01L 23/5283; H01L 27/11556; H01L 27/11519; H01L 27/11565

(57) ABSTRACT

There are provided a semiconductor device and a manufacturing method of the semiconductor device. The semiconductor device includes: a gate structure including conductive layers and insulating layers, which are alternately stacked; a plurality of channel structures penetrating the gate structure, the plurality of channel structures being arranged in a first direction; a plurality of cutting structures each isolating each of the plurality of channel structures, respectively, into a plurality of divided channel structures while penetrating each of the plurality of channel structures, respectively; and a plurality of interconnection lines located over the gate structure and extending in the first direction. Each of the plurality of cutting structures has substantially a cross (+) shape including extension parts extending in directions oblique to the first direction.

### CROSS-REFERENCE TO RELATED APPLICATION

The present application claims priority under 35 U.S.C. § 119(a) to Korean patent application number 10-2022-0033604 filed on Mar. 17, 2022, in the Korean Intellectual Property Office, the entire disclosure of which is incorporated by reference herein.

### BACKGROUND

### 1. Technical Field

The present disclosure generally relates to an electronic device, and more particularly, to a semiconductor device and a manufacturing method of the semiconductor device.

### 2. Related Art

A nonvolatile memory device is a memory device in which stored data is retained as it is even when the supply of power is interrupted. As the improvement of the degree of integration of two-dimensional nonvolatile memory devices in which memory cells are formed in the form of a single layer over a substrate reaches the limit, there has recently been proposed a three-dimensional nonvolatile memory device in which memory cells are stacked vertically over a substrate.

The three-dimensional nonvolatile memory device includes interlayer insulating layers and gate electrodes, which are alternately stacked, and channel layers penetrating the interlayer insulating layers and the gate electrodes, and memory cells are stacked along the channel layers. Various structures and various manufacturing methods have been developed to improve the operational reliability of such a nonvolatile memory device having a three-dimensional structure.

### SUMMARY

In accordance with an embodiment of the present disclosure, there is provided a semiconductor device including: a gate structure including conductive layers and insulating layers, which are alternately stacked; a plurality of channel structures penetrating the gate structure, the plurality of channel structures being arranged in a first direction; a plurality of cutting structures each isolating each of the plurality of channel structures, respectively, into a plurality of divided channel structures while penetrating each of the plurality of channel structures, respectively; and a plurality of interconnection lines located over the gate structure and extending in the first direction, wherein each of the plurality of cutting structures has substantially a cross (+) shape including extension parts extending in directions oblique to the first direction.

In accordance with another embodiment of the present disclosure, there is provided a semiconductor device including: a gate structure including conductive layers and insulating layers, which are alternately stacked; a plurality of channel structures penetrating the gate structure, the plurality of channel structures being arranged in a first direction; and a plurality of interconnection lines disposed on the top of the plurality of channel structures, the plurality of interconnection lines extending in the first direction, wherein each of the plurality of channel structures includes a plurality of divided channel structures and a cutting structure isolating the plurality of divided channel structures from each other, and wherein the cutting structure includes extension parts extending in directions oblique to the first direction.

In accordance with still another embodiment of the present disclosure, there is provided a method of manufacturing a semiconductor device, the method including: forming a stack structure; forming channel structures penetrating the stack structure, the channel structures being arranged in a first direction; and forming a plurality of cutting structures, wherein each of the plurality of cutting structures penetrates each of the channel structures, respectively, in a vertical direction, isolates each of the channel structures into a plurality of divided channel structures, and each of the cutting structures includes extension parts extending in directions oblique to the first direction.

### BRIEF DESCRIPTION OF THE DRAWINGS

Examples of embodiments will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a semiconductor device in accordance with an embodiment of the present disclosure.

FIGS. 2A, 2B, and 2C are views illustrating a structure of a semiconductor device in accordance with an embodiment of the present disclosure.

FIG. 3 is a view illustrating a structure of a semiconductor device in accordance with another embodiment of the present disclosure.

FIG. 4 is a view illustrating a structure of a semiconductor device in accordance with still another embodiment of the present disclosure.

FIGS. 5A, 5B, 6A, 6B, 7A, 7B, 8A, 8B, 9A, and 9B are views illustrating a manufacturing method of a semiconductor device in accordance with an embodiment of the present disclosure.

FIG. 10 is a diagram illustrating a memory system in accordance with an embodiment of the present disclosure.

FIG. 11 is a diagram illustrating a memory system in accordance with an embodiment of the present disclosure.

FIG. 12 is a diagram illustrating a memory system in accordance with an embodiment of the present disclosure.

FIG. 13 is a diagram illustrating a memory system in accordance with an embodiment of the present disclosure.

FIG. 14 is a diagram illustrating a memory system in accordance with an embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Embodiments provide a semiconductor device having an increased degree of integration of memory cells, and a manufacturing method of the semiconductor device.

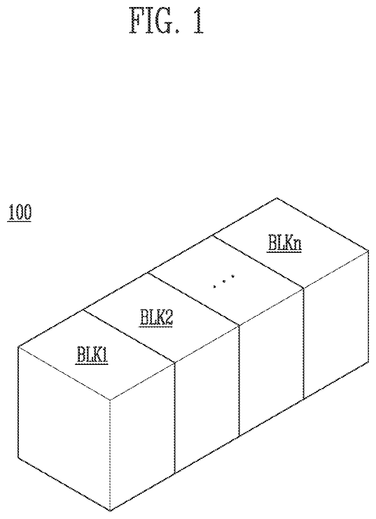

FIG. 1 is a block diagram illustrating a semiconductor device in accordance with an embodiment of the present disclosure.

Referring to FIG. 1, the semiconductor device 100 may include a plurality of memory blocks BLK1 to BLKn.

Each of the memory blocks BLK1 to BLKn may include a source line, bit lines, memory cell strings electrically connected to the source line and the bit lines, word lines electrically connected to the memory cell strings, and select lines electrically connected to the memory cell strings. Each of the memory cell strings may include memory cells and select transistors, which are connected in series by a channel pattern. The select lines and the word lines may be used as gate electrodes of the select transistors and the memory cells.

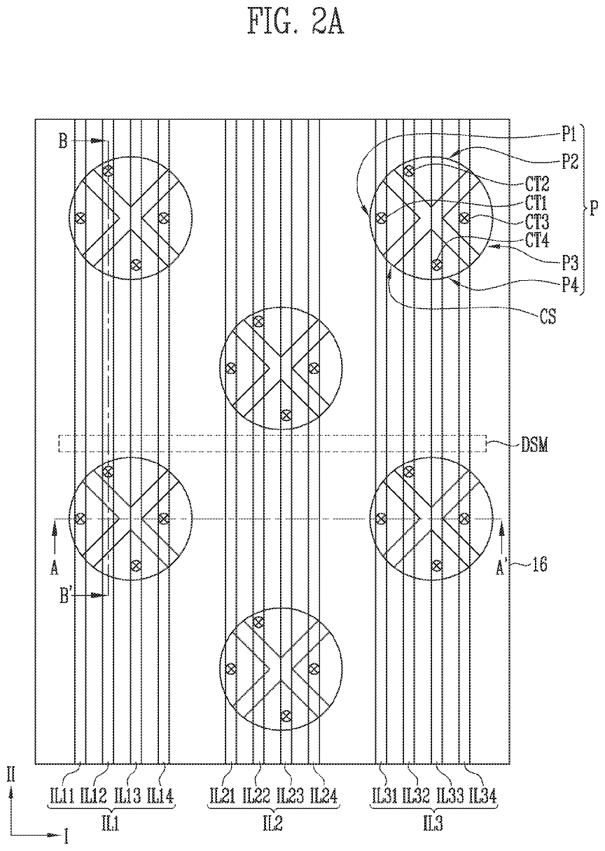

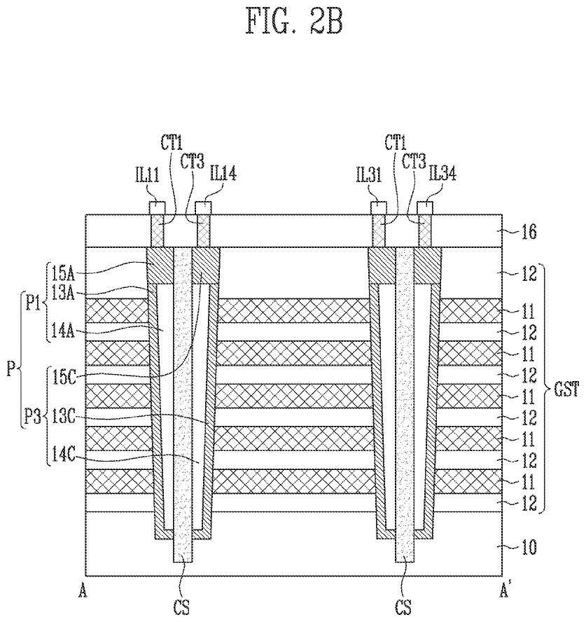

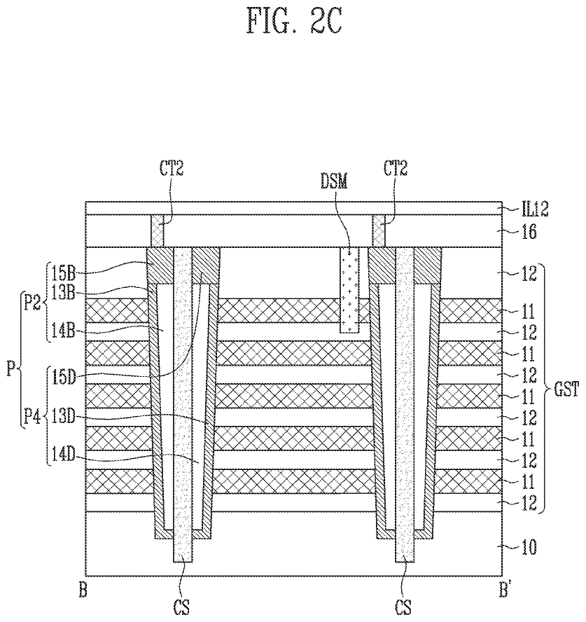

FIGS. 2A to 2C are views illustrating a structure of a semiconductor device in accordance with an embodiment of the present disclosure. FIG. 2A is a layout view of a layer in which an interlayer insulating layer 16 of the semiconductor device, and 2B and 2C are sectional views of memory strings.

Referring to FIGS. 2A to 2C, the semiconductor device may include a gate structure GST, pillar structures P, a cutting structure CS, a plurality of contacts CT1, CT2, CT3, and CT4, and a plurality of interconnection lines IL1, IL2, and IL3. The semiconductor device may further include a base 10 and a slit structure (not shown) or further include a combination thereof.

The gate structure GST may include conductive layers 11 and insulating layers 12, which are alternately stacked. The conductive layers 11 may be gate electrodes of a memory cell, a select transistor, and the like. For example, at least one conductive layer 11 located at an uppermost portion among the conductive layers 11 may be a gate electrode of a select transistor, and the other conductive layers 11 may be gate electrodes of memory cells. For example, at least one conductive layer 11 located at an uppermost portion and at least one conductive layer 11 located at a lowermost portion among the conductive layers 11 may be gate electrodes of select transistors, and the other conductive layers 11 may be gate electrodes of memory cells. The conductive layers 11 may include a conductive material such as poly-silicon, tungsten, molybdenum or metal. The insulating layers 12 may be used to insulate the stacked conductive layers 11 from each other. The insulating layers 12 may include an insulating material such as oxide, nitride or an air gap.

The gate structure GST may be located on the base 10. The base 10 may be a semiconductor substrate, a source layer, or the like. The semiconductor substrate may include a source region doped with an impurity. The source layer may include a conductive material such as poly-silicon, tungsten, molybdenum or metal.

The pillar structures P may penetrate the gate structure GST. The pillar structures P may be arranged in a first direction I as a horizontal direction of the base 10 and a second direction II intersecting the first direction I. In an embodiment, the pillar structures P may be arranged in a matrix form.

Each of the pillar structures P may include at least four pillar structures, i.e., a first pillar structure P1, a second pillar structure P2, a third pillar structure P3, and a fourth pillar structure P4. By the cutting structure CS, the pillar structure P may be divided into the first pillar structure P1, the second pillar structure P2, the third pillar structure P3, and the fourth pillar structure P4 which are all isolated from each other. In an embodiment, the first pillar structure P1, the second pillar structure P2, the third pillar structure P3, and the fourth pillar structure P4 may have structures symmetrical to each other with the cutting structure CS interposed therebetween.

The cutting structure CS may extend while penetrating the pillar structures P in a vertical direction. The cutting structure CS may extend to the base 10 while penetrating the pillar structures P. The cutting structure CS may include an insulating material such as oxide, nitride or an air gap.

In an embodiment, the cutting structure CS may have a cross (+) shape. The cutting structure CS may extend in oblique directions of an extending direction of the plurality of interconnection lines IL1, IL2, and IL3, e.g., the second direction II. The cutting structure CS may include a line-shaped first extension part extending in a third direction and a line-shaped second extension part extending in a fourth direction, and the first extension part and the second extension part may cross each other. Each of the third direction and the fourth direction may be an oblique direction of the extending direction of the plurality of interconnection lines IL1, IL2, and IL3, e.g., the second direction II. By the cutting structure CS, the first pillar structure P1 may have a structure symmetrical in oblique directions to the second pillar structure P2 and the fourth pillar structure P4. By the cutting structure CS, the first pillar structure P1 may have a structure symmetrical in the first direction I to the third pillar structure P3.

In the above-described embodiments, it has been described that one pillar structure P includes at least four pillar structures, and the cutting structure CS penetrates the pillar structure P. However, the cutting structure CS may be a structure included in the pillar structure P. For example, one pillar structure P may include at least four pillar structures and one cutting structure CS, and the at least four pillar structures may be physically separated or physically isolated from each other by the cutting structure CS.

In an embodiment, each of the pillar structures P may be a channel structure including a channel layer 13A, 13B, 13C or 13D. The first pillar structure P1 may be a first channel structure, the second pillar structure P2 may be a second channel structure, the third pillar structure P3 may be a third channel structure, and the fourth pillar structure P4 may be a fourth channel structure. First memory cells or select transistors may be located at positions at which the first pillar structure P1 and the conductive layers 11 intersect each other, and second memory cells or select transistors may be located at positions at which the second pillar structure P2 and the conductive layers 11 intersect each other. In addition, third memory cells or select transistors may be located at positions at which the third pillar structure P3 and the conductive layers 11 intersect each other, and fourth memory cells or select transistors may be located at positions at which the fourth pillar structure P4 and the conductive layers 11 intersect each other. A first memory cell, a second memory cell, a third memory cell, and a fourth memory cell, which are adjacent to each other with the cutting structure CS interposed therebetween, may be individually driven. In an embodiment, referring to FIG. 2A, the cutting structure CS may divide the pillar structure P into first to fourth pillar structures P1, P2, P3, and P4 or generally referred to as a plurality of divided channel structures. Here, for example in FIG. 2A, it is shown that each pillar structure P has been divided into four divided channel structures (i.e., P1, P2, P3, and P4) by the cutting structure CS.

The first pillar structure P1 may include a first channel layer 13A. The first channel layer 13A may be a region in which a channel of a memory cell, a select transistor, or the like is formed. The first channel layer 13A may include a semiconductor material such as silicon or germanium. The first pillar structure P1 may further include a first conductive pad 15A. The first conductive pad 15A may be connected to the first channel layer 13A, and include a conductive material. The first pillar structure P1 may further include a first insulating core 14A. The first insulating core 14A may include an insulating material such as oxide, nitride or an air gap. The first pillar structure P1 may further include a memory layer (not shown) located between the first channel layer 13A and the conductive layers 11. The memory layer may include at least one of a tunneling layer, a data storage layer, and a blocking layer. The data storage layer may include a floating gate, a charge trap material, poly-silicon, nitride, a variable resistance material, or a nano structure, or include any combination thereof.

The second pillar structure P2 may have a structure similar to the structure of the first pillar structure P1. The second pillar structure P2 may include a second channel layer 13B. The second pillar structure P2 may further include a second conductive pad 15B or a second insulating core 14B, or further include a combination thereof.

The third pillar structure P3 may have a structure similar to the structure of the first pillar structure P1. The third pillar structure P3 may include a third channel layer 13C. The third pillar structure P3 may further include a third conductive pad 15C or a third insulating core 14C, or further include a combination thereof.

The fourth pillar structure P4 may have a structure similar to the structure of the first pillar structure P1. The fourth pillar structure P4 may include a fourth channel layer 13D. The fourth pillar structure P4 may further include a fourth conductive pad 15D or a fourth insulating core 14D, or further include a combination thereof.

In an embodiment, each of the pillar structures P may be an electrode structure including an electrode layer. The first pillar structure P1 may be a first electrode structure, the second pillar structure P2 may be a second electrode structure, the third pillar structure P3 may be a third electrode structure, and the fourth pillar structure P4 may be a fourth electrode structure. The first electrode structure may include a first electrode layer instead of the first channel layer 13A. The first electrode structure may further include the first conductive pad 15A or the first insulating core 14A, or further include a combination thereof. The first pillar structure P1 may further include a memory layer located between the first electrode layer and the conductive layers 11. The second electrode structure may include a second electrode layer instead of the second channel layer 13B. The second electrode structure may further include the second conductive pad 15B or the second insulating core 14B, or further include a combination thereof. The second pillar structure P2 may further include a memory layer located between the second electrode layer and the conductive layers 11. The third electrode structure may include a third electrode layer instead of the third channel layer 13C. The third electrode structure may further include the third conductive pad 15C or the third insulating core 14C, or further include a combination thereof. The third pillar structure P3 may further include a memory layer located between the third electrode layer and the conductive layers 11. The fourth electrode structure may include a fourth electrode layer instead of the fourth channel layer 13D. The fourth electrode structure may further include the fourth conductive pad 15D or the fourth insulating core 14D, or further include a combination thereof. The fourth pillar structure P4 may further include a memory layer located between the fourth electrode layer and the conductive layers 11.

A drain select line isolation structure DSM may penetrate the gate structure GST to a depth shallower than a depth of the cutting structure CS. The drain select line isolation structure DSM may have a depth to which the drain select line isolation structure DSM penetrates at least one conductive layer 11 at an uppermost portion. In an embodiment, the drain select line isolation structure DSM may have a depth to which the drain select line isolation structure DSM penetrates at least one conductive layer corresponding to a select line among the conductive layers 11, and does not penetrate any conductive layers 11 corresponding to word lines.

The interlayer insulating layer 16 may be disposed on the gate structure GST, a first contact CT1 in contact with the first pillar structure P1 while penetrating the interlayer insulating layer 16, a second contact CT2 in contact with the second pillar structure P2 while penetrating the interlayer insulating layer 16, a third contact CT3 in contact with the third pillar structure P3 while penetrating the interlayer insulating layer 16, and a fourth contact CT4 in contact with the fourth pillar structure P4 while penetrating the interlayer insulating layer 16 may be disposed in the interlayer insulating layer 16.

A plurality of first interconnection lines IL1, a plurality of second interconnection lines IL2, and a plurality of third interconnection lines IL3 may extend in the second direction II. The plurality of first interconnection lines IL1, the plurality of second interconnection lines IL2, and the plurality of third interconnection lines IL3 may extend in a direction oblique to the first extension part and the second extension part of the cutting structure CS.

In an embodiment, each of first contacts CT1 may be connected to each of interconnection lines IL11, IL21, and IL31, each of second contacts CT2 may be connected to each of interconnection lines IL12, IL22, and IL32, each of third contacts CT3 may be connected to each of interconnection lines IL14, IL24, and IL34, and each of fourth contacts CT4 may be connected to each of interconnection lines IL13, IL23, and IL33.

The first contact CT1, the second contact CT2, the third contact CT3, and the fourth contact CT4 may be disposed at different levels of the first direction I to correspond to each of a plurality of first interconnection lines IL1, a plurality of second interconnection lines IL2, and a plurality of third interconnection lines IL3.

Although a case where contacts adjacent to each other in the second direction II may be disposed on the same line in the second direction II has been illustrated in the above-described embodiment, the present disclosure is not limited thereto, and contacts adjacent to each other in the second direction II may be disposed in a diagonal direction. Contacts adjacent to each other in the first direction I or the second direction II may be preferably disposed such that a distance between the contacts is maximally wide.

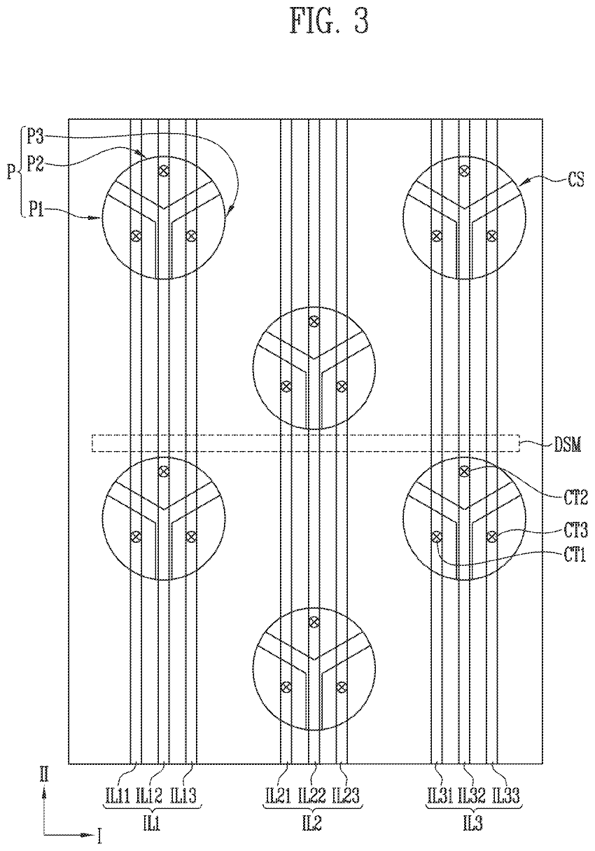

FIG. 3 is a view illustrating a structure of a semiconductor device in accordance with another embodiment of the present disclosure.

Referring to FIG. 3, a plurality of pillar structures P included in the semiconductor device may be arranged in a first direction I and a second direction II intersecting the first direction I. In an embodiment, the pillar structures P may be arranged in a matrix form.

Each of the pillar structures P may include at least three pillar structures, i.e., a first pillar structure P1, a second pillar structure P2, and a third pillar structure P3. By a cutting structure CS, the pillar structure P may be divided into a first pillar structure P1, a second pillar structure P2, and a third pillar structure P3 which are all isolated from each other. The first pillar structure P1, the second pillar structure P2, and the third pillar structure P3 may have structures symmetrical to each other with the cutting structure CS interposed therebetween.

The cutting structure CS may extend while penetrating the pillar structures P in a vertical direction. In an embodiment, referring to FIG. 3, the cutting structure CS may divide the pillar structure P into first to third pillar structures P1, P2, and P3 or generally referred to as a plurality of divided channel structures. Here, for example in FIG. 3, it is shown that each pillar structure P has been divided into three divided channel structures (i.e., P1, P2, and P3) by the cutting structure CS. The cutting structure CS may include an insulating material such as oxide, nitride or an air gap.

The cutting structure CS may have a Y shape. A portion of the cutting structure CS may extend in oblique directions of an extending direction of a plurality of interconnection lines IL1, IL2, and IL3, e.g., the second direction II. The cutting structure CS may include a line-shaped first extension part extending in a third direction, a line-shaped second extension part extending in a fourth direction, and a line-shaped third extension part extending in the second direction II. The first to third extension parts may be connected to one another in a central region of the pillar structure P. Each of the third direction and the fourth direction may be an oblique direction of the extending direction of the plurality of interconnection lines IL1, IL2, and IL3, e.g., the second direction II.

A drain select line isolation structure DSM may penetrate to a depth shallower than a depth of the cutting structure CS.

The semiconductor device may include a first contact CT1 in contact with the first pillar structure P1, a second contact CT2 in contact with the second pillar structure P2, and a third contact CT3 in contact with the third pillar structure P3.

A plurality of first interconnection lines IL1, a plurality of second interconnection lines IL2, and a plurality of third interconnection lines IL3 may extend in the second direction II. The plurality of first interconnection lines IL1, the plurality of second interconnection lines IL2, and the plurality of third interconnection lines IL3 may extend in oblique directions from the first and second extension parts.

In an embodiment, each of first contacts CT1 may be connected to each of interconnection lines IL11, IL21, and IL31, each of second contacts CT2 may be connected to each of interconnection lines IL12, IL22, and IL32, and each of third contacts CT3 may be connected to each of interconnection lines IL13, IL23, and IL33.

The first contact CT1, the second contact CT2, and the third contact CT3 may be disposed at different levels of the first direction I to correspond to each of a plurality of first interconnection lines IL1, a plurality of second interconnection lines IL2, and a plurality of third interconnection lines IL3.

The pillar structure P of the semiconductor device in accordance with the above-described embodiment may have a structure similar to the structure of the pillar structure P described above with reference to FIGS. 2B and 2C, and its detailed description will be omitted.

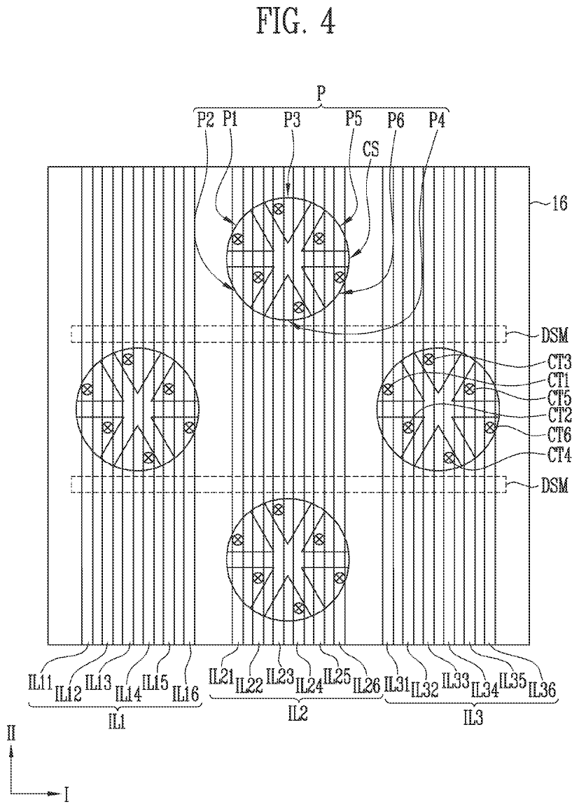

FIG. 4 is a view illustrating a structure of a semiconductor device in accordance with still another embodiment of the present disclosure.

Referring to FIG. 4, a plurality of pillar structures P included in the semiconductor device may be arranged in a first direction I and a second direction II intersecting the first direction I. In an embodiment, the pillar structures P may be arranged in a matrix form.

Each of the pillar structures P may include at least six pillar structures, i.e., a first pillar structure P1, a second pillar structure P2, a third pillar structure P3, a fourth pillar structure P4, a fifth pillar structure P5, and a sixth pillar structure P6. By a cutting structure CS, the pillar structure may be divided into a first pillar structure P1, a second pillar structure P2, a third pillar structure P3, a fourth pillar structure P4, a fifth pillar structure P5, and a sixth pillar structure P6 which are all isolated from each other. The first pillar structure P1, the second pillar structure P2, the third pillar structure P3, the fourth pillar structure P4, the fifth pillar structure P5, and the sixth pillar structure P6 may have structures symmetrical to each other with the cutting structure CS interposed therebetween. In an embodiment, referring to FIG. 4, the cutting structure CS may divide the pillar structure P into first to sixth pillar structures P1, P2, P3, P4, P5, and P6 or generally referred to as a plurality of divided channel structures. Here, for example in FIG. 4, it is shown that each pillar structure P has been divided into six divided channel structures (i.e., P1, P2, P3, P4, P5, and P6) by the cutting structure CS.

The cutting structure CS may extend while penetrating the pillar structures P in a vertical direction. The cutting structure CS may include an insulating material such as oxide, nitride or an air gap.

The cutting structure CS may have an asterisk (*) shape including extension parts extending in six directions. A portion of the cutting structure CS may include extension parts extending in oblique directions of an extending direction of a plurality of interconnection lines IL1, IL2, and IL3, e.g., the second direction II. The cutting structure CS may include line-shaped first and second extension parts extending in a third direction, line-shaped third and fourth extension parts extending a fourth direction, and line-shaped fifth and sixth extension parts extending in the first direction I, and the first to sixth extension parts may be connected to one another in a central region of the pillar structure P. Each of the third direction and the fourth direction may be an oblique direction of the extending direction of the plurality of interconnection lines IL1, IL2, and IL3, e.g., the second direction II.

A drain select line isolation structure DSM may penetrate to a depth shallower than a depth of the cutting structure CS.

The semiconductor device may include a first contact CT1 in contact with the first pillar structure P1, a second contact CT2 in contact with the second pillar structure P2, a third contact CT3 in contact with the third pillar structure P3, a fourth contact CT4 in contact with the fourth pillar structure P4, a fifth contact CT5 in contact with the fifth pillar structure P5, and a sixth contact CT6 in contact with the sixth pillar structure P6.

A plurality of first interconnection lines IL1, a plurality of second interconnection lines IL2, and a plurality of third interconnection lines IL3 may extend in the second direction II. The plurality of first interconnection lines IL1, the plurality of second interconnection lines IL2, and the plurality of third interconnection lines IL3 may extend in oblique directions from the first to fourth extension parts.

In an embodiment, each of first contacts CT1 may be connected to each of interconnection lines IL11, IL21, and IL31, each of second contacts CT2 may be connected to each of interconnection lines IL12, IL22, and IL32, each of third contacts CT3 may be connected to each of interconnection lines IL13, IL23, and IL33, each of fourth contacts CT4 may be connected to each of interconnection lines IL14, IL24, and IL34, each of fifth contacts CT5 may be connected to each of interconnection lines IL15, IL25, and IL35, and each of sixth contacts CT6 may be connected to each of interconnection lines IL16, IL26, and IL36.

The first contact CT1, the second contact CT2, the third contact CT3, the fourth contact CT4, the fifth contact CT5, and the sixth contact CT6 may be disposed at different levels of the first direction I to correspond to each of a plurality of first interconnection lines IL1, a plurality of second interconnection lines IL2, and a plurality of third interconnection lines IL3.

The pillar structure P of the semiconductor device in accordance with the above-described embodiment may have a structure similar to the structure of the pillar structure P described above with reference to FIGS. 2B and 2C, and its detailed description will be omitted.

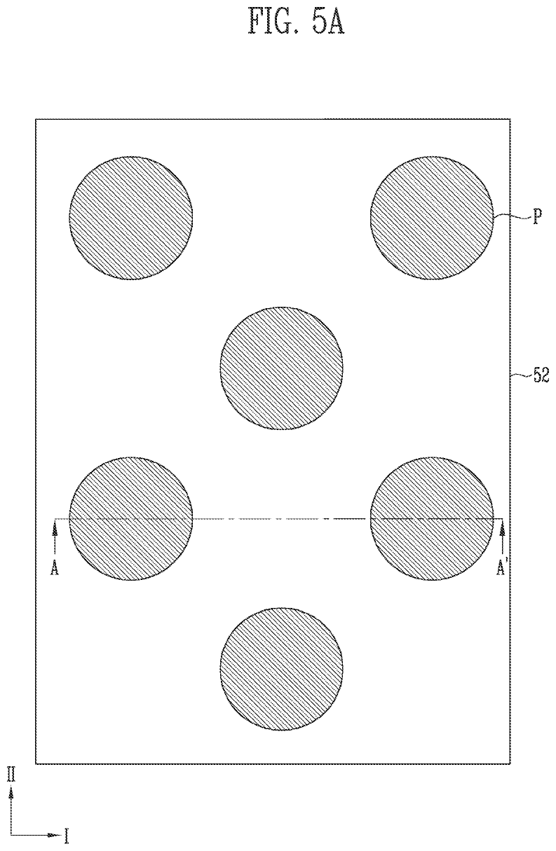

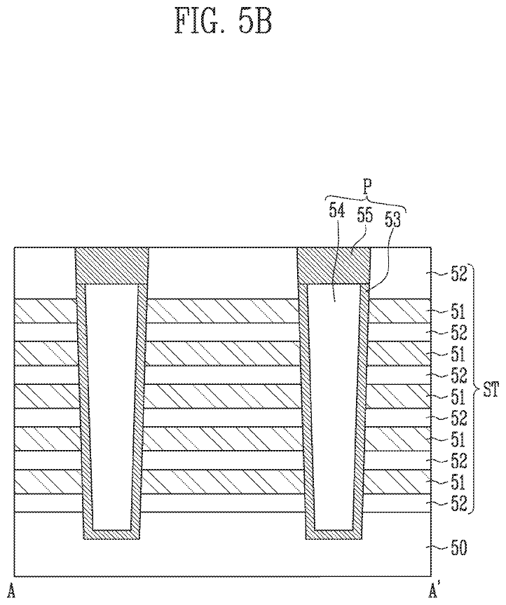

FIGS. 5A, 5B, 6A, 6B, 7A, 7B, 8A, 8B, 9A, and 9B are views illustrating a manufacturing method of a semiconductor device in accordance with an embodiment of the present disclosure.

Referring to FIGS. 5A and 5B, a stack structure ST may be formed on a base 50. The base 50 may be a semiconductor substrate, a source structure, or the like. The semiconductor substrate may include a source region doped with an impurity. The source structure may include a source layer including a conductive material such as poly-silicon, tungsten, molybdenum or metal. Alternatively, the source structure may include a sacrificial layer to be replaced with the source layer in a subsequent process.

First material layers 51 and second material layers 52 may be alternately formed, thereby forming the stack structure ST. The first material layers 51 may include a material having a high etch selectivity with respect to the second material layers 52. In an example, the first material layers 51 may include a sacrificial material such as nitride, and the second material layers 52 may include an insulating material such as oxide. In another example, the first material layers 51 may include a conductive material such as poly-silicon, tungsten or molybdenum, and the second material layers 52 may include an insulating material such as oxide.

Subsequently, pillar structures P may be formed, which penetrate the stack structure ST. The pillar structures P may be arranged in a first direction I and a second direction II intersecting the first direction I. Pillar structures P adjacent to each other in the first direction I may be arranged such that the centers of the pillar structures P accord with each other. Pillar structures P arranged in the second direction II may be arranged such that the centers of the pillar structures P are dislocated from each other.

On a plane defined in the first direction I and the second direction II, the pillar structure P may have a shape such as a circular shape, an elliptical shape, or a polygonal shape.

The pillar structures P may include a channel layer 53. In an embodiment, after an opening penetrating the stack structure ST is formed, the channel layer 53 may be formed in the opening. A memory layer may be formed before the channel layer 53 is formed. Subsequently, after an insulating core 54 is formed, a conductive pad 55 may be formed. The pillar structures P may include an electrode layer instead of the channel layer 55. The insulating core 54 may be omitted, or the conductive pad 55 may be omitted.

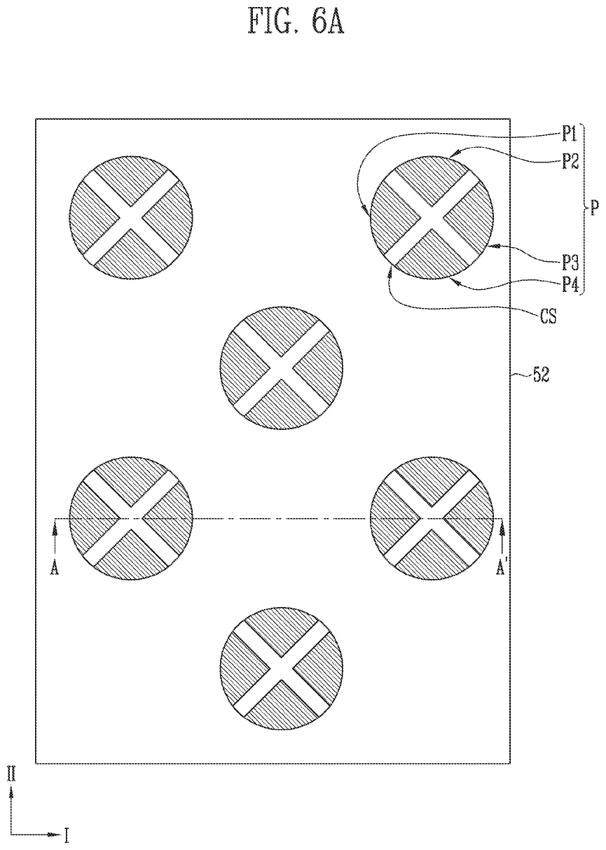

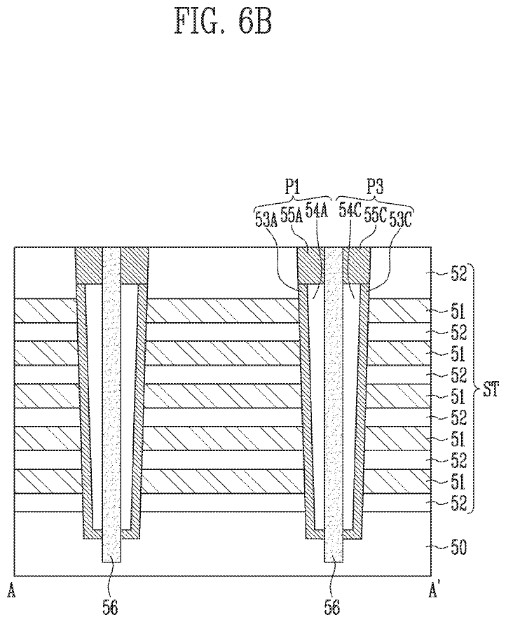

Referring to FIGS. 6A and 6B, cutting structures 56 (CS) may be formed. Each of the cutting structures 56 (CS) may extend in a vertical direction while penetrating one pillar structure P. By the cutting structures 56 (CS), each of the pillar structures P may be divided into a first pillar structure P1, a second pillar structure P2, a third pillar structure P3, and a fourth pillar structure P4 which are all isolated from each other. That is, one pillar structure P may be divided into four pillar structures P1 to P4 by one cutting structure 56 (CS) to isolate the four pillar structures P1 to P4 from one another.

The first pillar structure P1 may be a first channel structure, and the second pillar structure P2 may be a second channel structure. The third pillar structure P3 may be a third channel structure, and a fourth pillar structure P4 may be a fourth channel structure. Each of the first pillar structure P1, the second pillar structure P2, the third pillar structure P3, and the fourth pillar structure P4 may include a channel layer, an insulating core, and a conductive pad. For example, the first pillar structure P1 may include a first channel layer 53A, a first insulating core 54A, and a first conductive pad 55A. For example, the third pillar structure P3 may include a third channel layer 53C, a third insulating core 54C, and a third conductive pad 55C. Alternatively, the first pillar structure P1 may be a first electrode structure, the second pillar structure P2 may be a second electrode structure, the third pillar structure P3 may be a third electrode structure, and the fourth pillar structure P4 may be a fourth electrode structure.

In an embodiment, each of the cutting structures 56 (CS) may extend to the base 50 while penetrating the pillar structures P. Each of the cutting structures 56 (CS) may include an insulating material such as oxide, nitride or an air gap. Each of the cutting structures 56 (CS) may have a cross (+) shape. Each of the cutting structures 56 (CS) may include extension parts extending in oblique directions of the second direction II as an extending direction of a plurality of interconnection lines formed subsequently. For example, the cutting structure 56 (CS) may include a line-shaped first extension part extending in a third direction and a line-shaped second extension part extending in a fourth direction, and the first extension part and the second extension part may cross each other. Each of the third direction and the fourth direction may be an oblique direction of the second direction II as the extending direction of the plurality of interconnection lines. By the cutting structure 56 (CS), the first pillar structure P1 may have a structure symmetrical in oblique directions to the second pillar structure P2 and the fourth pillar structure P4. By the cutting structure 56 (CS), the first pillar structure P1 may have a structure symmetrical in the first direction I to the third pillar structure P3.

In an embodiment, a cross-shaped hole penetrating the pillar structures P may be formed by performing an etching process, and the cutting structure 56 (CS) may be formed by fill the formed hole with an insulating material.

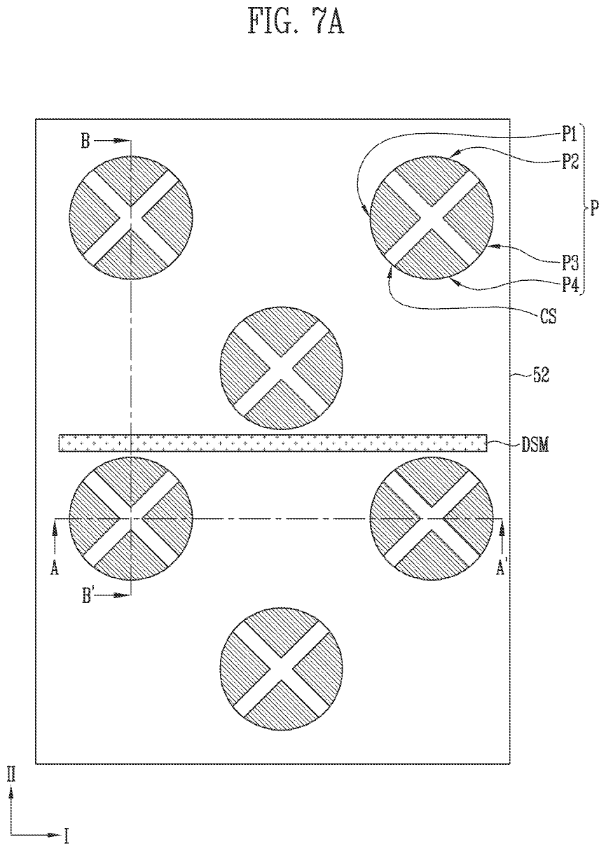

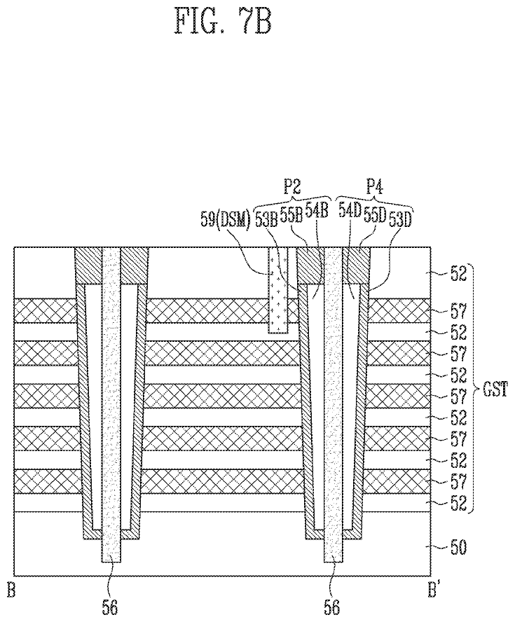

Referring to FIGS. 7A and 7B, a slit (not shown) may be formed, which penetrates the stack structure (ST shown in FIG. 6B). The slit (not shown) may be formed in a line shape extending in the first direction I or the second direction II. A sidewall of the stack structure ST may be exposed by the slit (not shown). Subsequently, the first material layers (51 shown in FIG. 6B) may be replaced with third material layers 57 through the slit (not shown). In an example, when the first material layers 51 are sacrificial layers and the second material layers 52 are insulating layers, the first material layers 51 may be replaced with conductive layers. After the first material layers 51 are selectively etched, the third material layers 57 may be formed in regions in which the first material layers 51 are etched. The memory layer may be formed before the third material layers 57 are formed. In another example, when the first material layers 51 are conductive layers and the second material layers 52 are insulating layers, the first material layers 51 may be silicided. Accordingly, a gate structure GST may be formed, in which the third material layers 57 and the second material layers 52 are alternately stacked.

Subsequently, a drain select line isolation structure 59 (DSM) may be formed, which penetrates the gate structure GST. The drain select line isolation structure 59 (DSM) may penetrate to a depth shallower than a depth of the cutting structure 56 (CS). The drain select line isolation structure 59 (DSM) may extend in the first direction I. On a plane defined in the first direction I and the second direction II, the drain select line isolation structure 59 (DSM) may have a linear shape or have a zigzag shape, a wave shape, or the like.

The drain select line isolation structure 59 (DSM) may be formed between the pillar structures P.

In an embodiment, the drain select line isolation structure 59 (DSM) may be formed by forming a trench penetrating at least one third material layer among the third material layers 57 included in the gate structure GST, and filling the trench with an insulating material.

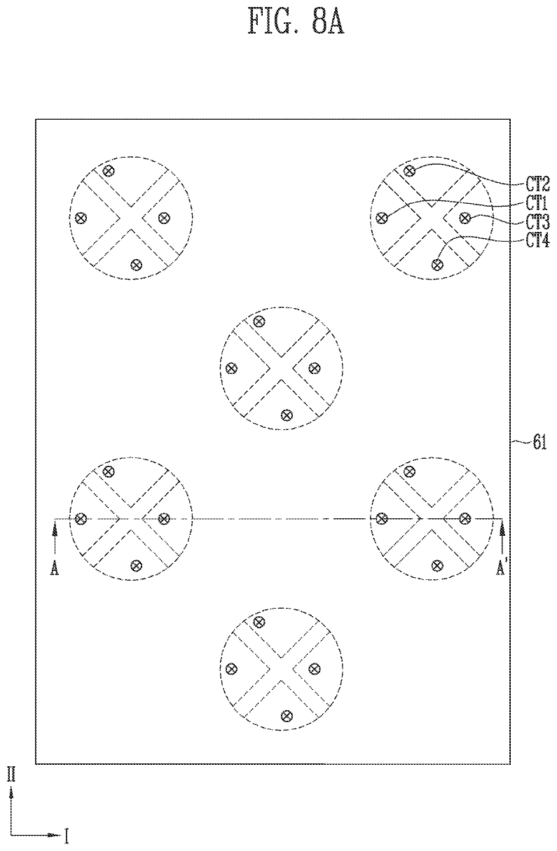

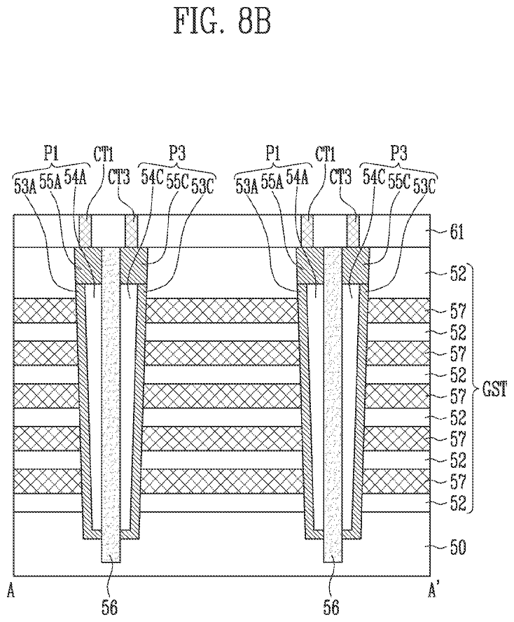

Referring to FIGS. 8A and 8B, an interlayer insulating layer 61 may be formed on the gate structure GST. Subsequently, a first contact CT1, a second contact CT2, a third contact CT3, and a fourth contact CT4 may be formed, which respectively correspond to the first pillar structure P1, the second pillar structure P2, the third pillar structure P3, and the fourth pillar structure P4 while penetrating the interlayer insulating layer 61. For example, the first contact CT1 may be directly connected to the first conductive pad 55A of the first pillar structure P1, the second contact CT2 may be directly connected to the second conductive pad (55B shown in FIG. 7B) of the second pillar structure P2, the third contact may be directly connected to the third conductive pad 55C of the third pillar structure P3, and the fourth contact CT4 may be directly connected to the fourth conductive pad (55D shown in FIG. 7D) of the fourth pillar structure P4.

In an embodiment, the first contact CT1, the second contact CT2, the third contact CT3, and the fourth contact CT4 may be formed by forming contact holes through which upper surfaces of the first pillar structure P1, the second pillar structure P2, the third pillar structure P3, and the fourth pillar structure P4 are respectively exposed through etching of the interlayer insulating layer 61, and filling the contact holes with a conductive material.

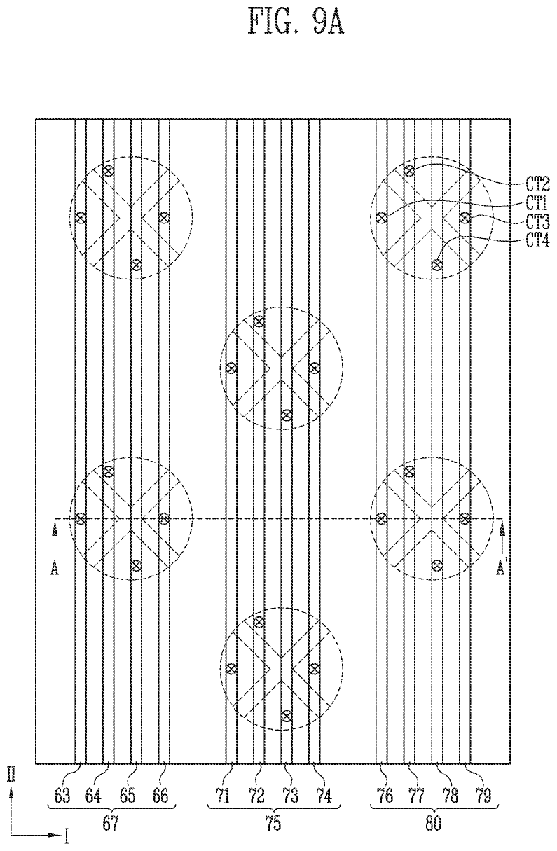

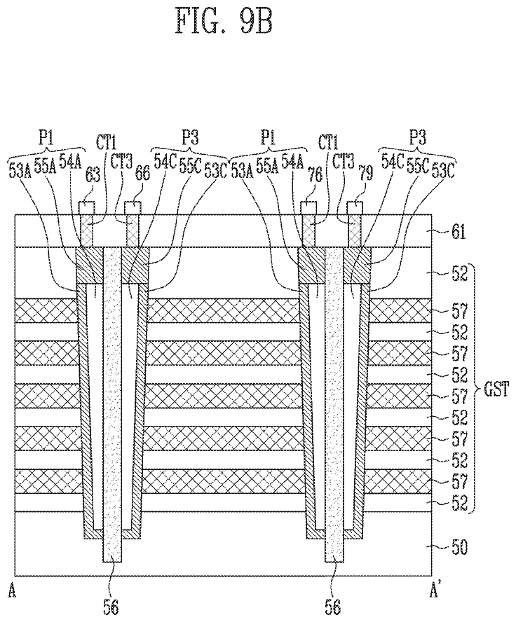

Referring to FIGS. 9A and 9B, a plurality of interconnection lines 67, 75, and 80 may be formed on the top of the interlayer insulating layer 61.

A first interconnection line 67, a second interconnection line 75, and a third interconnection line 80 may extend in the second direction II. The first interconnection line 67, the second interconnection line 75, and the third interconnection line 80 may extend in a direction oblique to extending directions of the extension parts of the cutting structure CS.

In an embodiment, each of the first contacts CT1 may be connected to each of interconnection lines 63, 71, and 76, each of second contacts CT2 may be connected to each of interconnection lines 64, 72, and 77, each of third contacts CT3 may be connected to each of interconnection lines 66, 74, and 79, and each of fourth contacts CT4 may be connected to each of interconnection lines 65, 73, and 78.

As described above, in accordance with the embodiment of the present disclosure, one pillar structure P is divided into a plurality of pillar structures P1 to P4 by using the cutting structure CS to isolate the plurality of pillar structures P1 to P4 from each other, and the extension parts of the cutting structure CS are formed to extend in directions oblique to an extending directions of the interconnection lines. Accordingly, the plurality of pillar structures P1 to P4 may be disposed adjacent to each other in oblique directions. In an embodiment, this increases a width in the first direction I as compared with a case where a first pillar structure P1 and a second pillar structure P2 are disposed symmetrical to each other in the second direction II. Thus, according to an embodiment, in an arrangement process of interconnection lines (e.g., 63 and 64) corresponding to the first pillar structure P1 and the second pillar structure P2, a process margin can be secured.

In the embodiment of the present disclosure, it has been described that the forming of the drain select line isolation structure DSM shown in FIGS. 7A and 7B is performed after the forming of the cutting structure CS shown in FIGS. 6A and 6B is performed. However, the present disclosure is not limited thereto. In another embodiment, the forming of the cutting structure CS shown in FIGS. 6A and 6B may be performed after the forming of the drain select line isolation structure DSM shown in FIGS. 7A and 7B is performed.

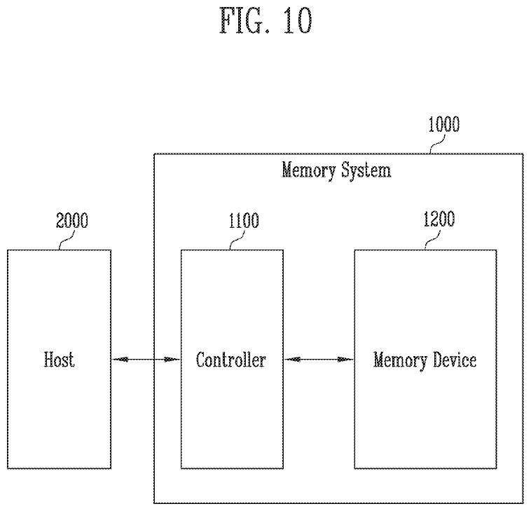

FIG. 10 is a diagram illustrating a memory system in accordance with an embodiment of the present disclosure.

Referring to FIG. 10, the memory system 1000 may include a memory device 1200 configured to store data and a controller 1100 configured to communicate between the memory device 1200 and a host 2000.

The host 2000 may be a device or system which stores data in the memory system 1000 or retrieves data from the memory system 1000. The host 2000 may generate requests for various operations, and output the generated requests to the memory system 1000. The requests may include a program request for a program operation, a read request for a read operation, an erase request for an erase operation, and the like. The host 2000 may communicate with the memory system 1000 through various interfaces such as Peripheral Component Interconnect-Express (PCI-E), Advanced Technology Attachment (ATA), Serial ATA (SATA), Parallel ATA (PATA), Serial Attached SCSI (SAS), or Non-Volatile Memory Express (NVMe), a Universal Serial Bus (USB), a Multi-Media Card (MMC), an Enhanced Small Disk Interface (ESDI), and Integrated Drive Electronics (IDE).

The host 2000 may include at least one of a computer, a portable digital device, a tablet, a digital camera, a digital audio player, a television, a wireless communication device, and a cellular phone, but embodiments of the present disclosure are not limited thereto.

The controller 1100 may control overall operations of the memory system 1000. The controller 1100 may control the memory device 1200 according to a request of the host 2000. The controller 1100 may control the memory device 1200 to perform a program operation, a read operation, an erase operation, and the like according to a request of the host 2000. Alternatively, the controller 1100 may perform a background operation, etc. for improving the performance of the memory system 1000 without any request of the host 2000.

The controller 1100 may transmit a control signal and a data signal to the memory device 1200 so as to control an operation of the memory device 1200. The control signal and the data signal may be transmitted to the memory device 1200 through different input/output lines. The data signal may include a command, an address or data. The control signal may be used to distinguish a period in which the data signal is input.

The memory device 1200 may perform a program operation, a read operation, an erase operation, and the like under the control of the controller 1100. The memory device 1200 may be implemented with a volatile memory device in which stored data disappears when the supply of power is interrupted or a nonvolatile memory device in which stored data is retained even when the supply of power is interrupted. The memory device 1200 may be a semiconductor device having the structure described above with reference to FIG. 2A to 2C, 3 or 4. The memory device 1200 may be a semiconductor device manufactured by the manufacturing method described above with reference to FIGS. 5A, 5B, 6A, 6B, 7A, 7B, 8A, 8B, 9A, and 9B.

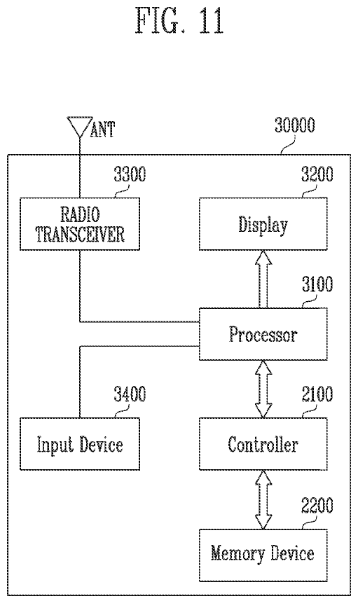

FIG. 11 is a diagram illustrating a memory system in accordance with an embodiment of the present disclosure.

Referring to FIG. 11, the memory system 30000 may be implemented as a cellular phone, a smart phone, a tablet PC, a personal digital assistant (PDA), or a wireless communication device. The memory system 30000 may include a memory device 2200 and a controller 2100 capable of controlling an operation of the memory device 2200.

The controller 2100 may control a data access operation of the memory device 2200, e.g., a program operation, an erase operation, a read operation, or the like under the control of a processor 3100.

Data programmed in the memory device 2200 may be output through a display 3200 under the control of the controller 2100.

A radio transceiver 3300 may transmit/receive radio signals through an antenna ANT. For example, the radio transceiver 3300 may change a radio signal received through the antenna ANT into a signal that can be processed by the processor 3100. Therefore, the processor 3100 may process a signal output from the radio transceiver 3300 and transmit the processed signal to the controller 2100 or the display 3200. The controller 2100 may transmit the signal processed by the processor 3100 to the memory device 2200. Also, the radio transceiver 3300 may change a signal output from the processor 3100 into a radio signal, and output the changed radio signal to an external device through the antenna ANT. An input device 3400 is a device capable of inputting a control signal for controlling an operation of the processor 3100 or data to be processed by the processor 3100, and may be implemented as a pointing device such as a touch pad or a computer mount, a keypad, or a keyboard. The processor 3100 may control an operation of the display 3200 such that data output from the controller 2100, data output from the radio transceiver 3300, or data output from the input device 3400 can be output through the display 3200.

In some embodiments, the controller 2100 capable of controlling an operation of the memory device 2200 may be implemented as a part of the processor 3100, or be implemented as a chip separate from the processor 3100.

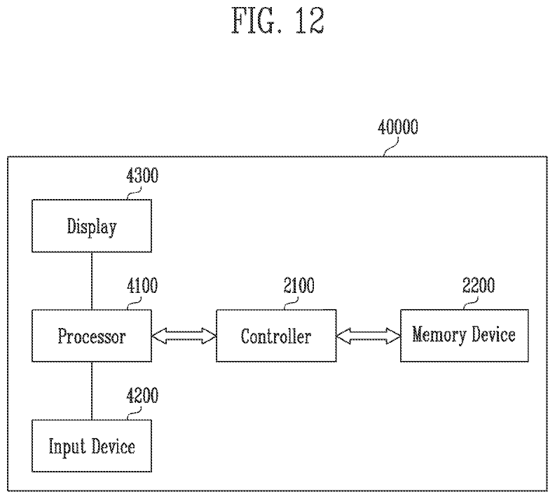

FIG. 12 is a diagram illustrating a memory system in accordance with an embodiment of the present disclosure.

Referring to FIG. 12, the memory system 40000 may be implemented as a personal computer (PC), a tablet PC, a net-book, an e-reader, a personal digital assistant (PDA), a portable multi-media player (PMP), an MP3 player, or an MP4 player.

The memory system 40000 may include a memory device 2200 and a controller 2100 capable of controlling a data processing operation of the memory device 2200.

A processor 4100 may output data stored in the memory device 2200 through a display 4300 according to data input through an input device 4200. For example, the input device 4200 may be implemented as a pointing device such as a touch pad or a computer mouse, a keypad, or a keyboard.

The processor 4100 may control overall operations of the memory system 40000, and control an operation of the controller 2100. In some embodiments, the controller 2100 capable of controlling an operation of the memory device 2200 may be implemented as a part of the processor 4100, or be implemented as a chip separate from the processor 4100.

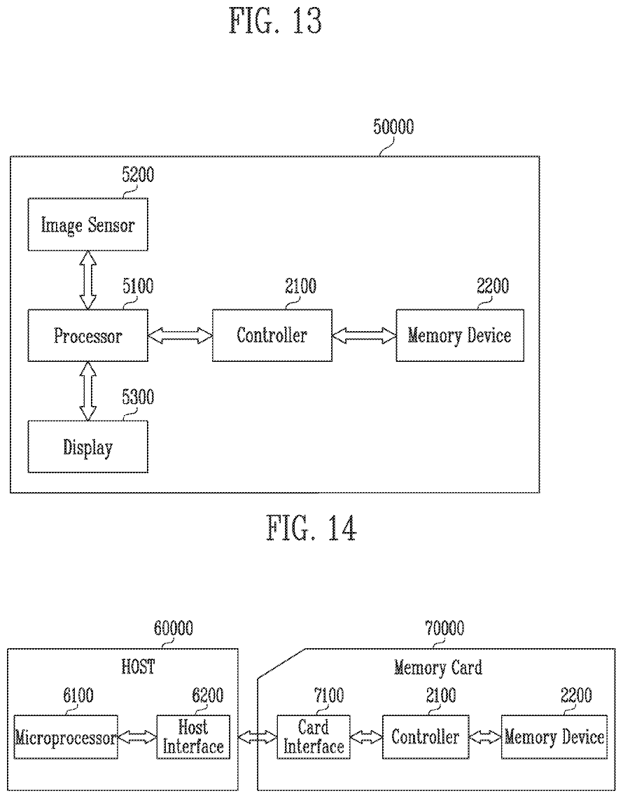

FIG. 13 is a diagram illustrating a memory system in accordance with an embodiment of the present disclosure.

Referring to FIG. 13, the memory system 50000 may be implemented as an image processing device, e.g., a digital camera, a mobile terminal having a digital camera attached thereto, a smart phone having a digital camera attached thereto, or a tablet PC having a digital camera attached thereto.

The memory system 50000 may include a memory device 2200 and a controller 2100 capable of controlling a data processing operation of the memory device 2200, e.g., a program operation, an erase operation, or a read operation.

An image sensor 5200 of the memory system 50000 may convert an optical image into digital signals, and the converted digital signals may be transmitted to a processor 5100 or the controller 2100. Under the control of the processor 5100, the converted digital signals may be output through a display 5300, or be stored in the memory device 2200 through the controller 2100. In addition, data stored in the memory device 2200 may be output through the display 5300 under the control of the processor 5100 or the controller 2100.

In some embodiments, the controller 2100 capable of controlling an operation of the memory device 2200 may be implemented as a part of the processor 5100, or be implemented as a chip separate from the processor 5100.

FIG. 14 is a diagram illustrating a memory system in accordance with an embodiment of the present disclosure.

Referring to FIG. 14, the memory system 70000 may be implemented as a memory card or a smart card. The memory system 70000 may include a memory device 2200, a controller 2100, and a card interface 7100.

The controller 2100 may control data exchange between the memory device 2200 and the card interface 7100. In some embodiments, the card interface 7100 may be a secure digital (SD) card interface or a multi-media card (MMC) interface, but the present disclosure is not limited thereto.

The card interface 7100 may interface data exchange between a host 60000 and the controller 2100 according to a protocol of the host 60000. In some embodiments, the card interface 7100 may support a universal serial bus (USB) protocol and an inter-chip (IC)-USB protocol. The card interface 7100 may mean hardware capable of supporting a protocol used by the host 60000, software embedded in the hardware, or a signal transmission scheme.

When the memory system 70000 is connected to a host interface 6200 of the host 60000 such as a PC, a tablet PC, a digital camera, a digital audio player, a cellular phone, console video game hardware, or a digital set-top box, the host interface 6200 may perform data communication with the memory device 2200 through the card interface 7100 and the controller 2100 under the control of a microprocessor 6100.

In accordance with an embodiment, one pillar structure is divided into a plurality of pillar structures by using a cutting structure to isolate the plurality of pillar structures from one another. Thus, in an embodiment, the number of memory cells implemented with one pillar structure can be increased.

While the present disclosure has been shown and described with reference to certain embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A semiconductor device comprising:
a gate structure including conductive layers and insulating layers, which are alternately stacked;
a plurality of channel structures penetrating the gate structure, the plurality of channel structures being arranged in a first direction;
a plurality of cutting structures each isolating each of the plurality of channel structures, respectively, into a plurality of divided channel structures while penetrating each of the plurality of channel structures, respectively; and
a plurality of interconnection lines located over the gate structure and extending in the first direction,
wherein each of the plurality of cutting structures has substantially a cross (+) shape including extension parts extending in directions oblique to the first direction.

2. The semiconductor device of claim 1, wherein each of the plurality of cutting structures extending in a vertical direction respectively penetrates each of the plurality of channel structures, and isolates each of the plurality of channel structures into a first divided channel structure, a second divided channel structure, a third divided channel structure, and a fourth divided channel structure by the extension parts extending in the oblique directions.

3. The semiconductor device of claim 2, wherein the first divided channel structure is symmetrical to the second divided channel structure adjacent thereto in the oblique direction with respect to the cutting structure, and
the fourth divided channel structure is symmetrical to the third divided channel structure adjacent thereto in the oblique direction with respect to the cutting structure.

4. The semiconductor device of claim 1, further comprising a plurality of contacts respectively connected to upper surfaces of the plurality of divided channel structures.

5. The semiconductor device of claim 4, wherein the plurality of contacts electrically connect the plurality of divided channel structures and the plurality of interconnection lines to each other.

6. The semiconductor device of claim 4, wherein the plurality of contacts are disposed at different levels of a second direction, the second direction being a vertical direction of the first direction.

7. The semiconductor device of claim 6, further comprising a drain select line isolation structure extending in the second direction while penetrating at least one conductive layer disposed at an uppermost portion among the alternately stacked conductive layers.

8. The semiconductor device of claim 1, wherein each of the channel structures includes a plurality of channel layers isolated from each other by the cutting structure.

9. A semiconductor device comprising:
a gate structure including conductive layers and insulating layers, which are alternately stacked;
a plurality of channel structures penetrating the gate structure, the plurality of channel structures being arranged in a first direction; and
a plurality of interconnection lines disposed on the top of the plurality of channel structures, the plurality of interconnection lines extending in the first direction,
wherein each of the plurality of channel structures includes a plurality of divided channel structures and a cutting structure isolating the plurality of divided channel structures from each other, and
wherein the cutting structure includes extension parts extending in directions oblique to the first direction.

10. The semiconductor device of claim 9, wherein the cutting structure has substantially a Y shape.

11. The semiconductor device of claim 10, wherein the cutting structure extending in a vertical direction isolates a first divided channel structure, a second divided channel structure, and a third divided channel structure from each other by allowing the first divided channel structure, the second divided channel structure, and the third divided channel structure to be spaced apart from each other by the extension parts extending in the oblique directions.

12. The semiconductor device of claim 11, wherein the first divided channel structure is symmetrical to the second divided channel structure adjacent thereto in the oblique direction with respect to the cutting structure.

13. The semiconductor device of claim 9, wherein the cutting structure has substantially an asterisk (*) shape.

14. The semiconductor device of claim 13, wherein the cutting structure extending in a vertical direction isolates six divided channel structures from each other by allowing the six divided channel structures to be spaced apart from each other by the extension parts extending in the oblique directions.

15. A method of manufacturing a semiconductor device, the method comprising:
forming a stack structure;
forming channel structures penetrating the stack structure, the channel structures being arranged in a first direction; and
forming a plurality of cutting structures, wherein each of the plurality of cutting structures penetrates each of the channel structures, respectively, in a vertical direction, isolates each of the channel structures into a plurality of divided channel structures, and each of the cutting structures includes extension parts extending in directions oblique to the first direction.

16. The method of claim 15, wherein, in the forming of the stack structure, a plurality of first material layers and a plurality of second material layers are alternately stacked.

17. The method of claim 16, further comprising:
performing an etching process such that sidewalls of the plurality of first material layers and the plurality of second material layers are exposed, after the cutting structure is formed; and
selectively removing the plurality of second material layers and then filling a plurality of third material layers in spaces in which the plurality of second material layers have been removed.

18. The method of claim 17, further comprising forming a drain select line isolation structure extending in a second direction as a vertical direction of the first direction while penetrating at least one third material layer disposed at an uppermost portion among the plurality of third material layers.

19. The method of claim 15, further comprising:
after the cutting structure is formed,
forming a plurality of contacts directly connected respectively to top portions of the plurality of divided channel structures.

20. The method of claim 19, further comprising:
after the forming of the plurality of contacts,
forming a plurality of interconnection lines extending in the first direction, the plurality of interconnection lines being connected to the plurality of contacts.
